(19) United States
(12) Patent Application Publication
(10) Pub. No.: US 2024/0021484 A1
(43) Pub. Date: Jan. 18, 2024

(54) SEMICONDUCTOR STRUCTURE AND PREPARATION METHOD

(71) Applicant: Changxin Memory Technologies, Inc., Hefei (CN)

(72) Inventors: Mengmeng WANG, HEFEI (CN); Yutong SHEN, HEFEI (CN)

(21) Appl. No.: 17/947,774

(22) Filed: Sep. 19, 2022

Related U.S. Application Data
(63) Continuation of application No. PCT/CN2022/108301, filed on Jul. 27, 2022.

(30) Foreign Application Priority Data
Jul. 14, 2022 (CN) 202210834427.6

(51) Int. Cl. H01L 21/8238; H01L 27/092; H01L 29/49; H01L 21/28; H01L 21/3213; H01L 21/3215

(52) U.S. Cl. CPC H01L 21/823842; H01L 27/092; H01L 29/4966; H01L 21/28088; H01L 21/32135; H01L 21/3215

(57) ABSTRACT

A semiconductor structure and a preparation method therefor are provided. The semiconductor structure includes: a substrate, a gate dielectric layer, a first gate in a PMOS region, and a second gate in an NMOS region. The substrate includes a PMOS region and an NMOS region; the gate dielectric layer is located on the substrate of the PMOS region and of the NMOS region. The first gate includes a first work function layer and a first gate electrode layer that are stacked. The first work function layer is formed based on a first doping treatment of an initial work function layer. The second gate includes a second work function layer and a second gate electrode layer that are stacked. The semiconductor structure and the preparing method provided in the present disclosure can alleviate uneven etching of a PMOS transistor and an NMOS transistor and improve the yield and reliability of semiconductor devices.

### CROSS-REFERENCE TO RELATED APPLICATIONS

This application is a continuation application of International Patent Application No. PCT/CN2022/108301, filed on Jul. 27, 2022, which claims priority of Chinese Patent Application No. 202210834427.6, filed on Jul. 14, 2022. The above-referenced applications are incorporated herein by reference in their entirety.

### TECHNICAL FIELD

Embodiments of the present disclosure relate to the field of semiconductors, and in particular, to a semiconductor structure and a preparation method.

### BACKGROUND

Main devices of integrated circuits, especially, very large scale integrated circuits, are metal-oxide-semiconductor field effect transistors (MOSFETs). With the development of the MOSFET technologies, the die sizes of the MOSFETs have been continuously shrinking according to the Moore's Law. Various secondary effects caused by the physical limits of the devices are gradually inevitable, and it becomes more and more difficult to scale down the feature sizes of the devices. In the field of manufacturing of MOSFET devices and circuits thereof, the greatest challenge is to overcome the problem of current leakage from the gate to the substrate caused by the reduction in the thickness of the polysilicon or the gate dielectric layer during miniaturization of the devices with a conventional MOS process. This seriously affects the performance of a semiconductor device. For this, a High-K Metal Gate (HKMG) stacked transistor is developed on the basis of a HKMG process, thereby effectively solving the foregoing technical problem.

At present, in a MOS process, the gate dielectric usually uses a high-k material instead of a conventional silicon dioxide (SiO₂). A metal is used as a gate electrode to match the high-k material to avoid the problems of gate loss and current leakage. A mainstream integrated circuit process in the industry including gate-last deposition or gate-first (HK-First) deposition is adopted. The key problem of the gate-first process is to control a threshold voltage of a PMOS transistor. By keeping metal gates of transistors in their respective work function ranges, the transistors can finally reach their expected threshold voltages Vₜ. It is necessary to adjust the work functions of work function layers of a PMOS transistor and an NMOS transistor, so that the PMOS transistor and the NMOS transistor reach their respective threshold voltages. Because the thicknesses of the work function layers of the PMOS transistor and the NMOS transistor are different, the method suffers from uneven etching in a subsequent etching process, which degrades the yield and reliability of semiconductor devices.

### SUMMARY

Embodiments of the present disclosure provide a semiconductor structure and a preparation method, which provide a solution to uneven etching of a PMOS transistor and an NMOS transistor, thereby improving the yield and reliability of semiconductor devices.

An embodiment of the present disclosure provides a semiconductor structure, including: a substrate, a gate dielectric layer, a first gate in a PMOS region, and a second gate in an NMOS region; the substrate includes the PMOS region and the NMOS region; the gate dielectric layer is located on the substrate of the PMOS region and of the NMOS region; the first gate includes a first work function layer and a first gate electrode layer that are stacked; the first work function layer is formed based on a first doping treatment of an initial work function layer; and the second gate includes a second work function layer and a second gate electrode layer that are stacked.

In some embodiments, the first work function layer is doped with first dopant ions, the first dopant ions including aluminum ions, cobalt ions, nickel ions, ruthenium ions, rhodium ions, palladium ions, rhenium ions, iridium ions, or platinum ions.

In some embodiments, the second work function layer is formed based on a second doping treatment of the same initial work function layer.

In some embodiments, the second work function layer is doped with second dopant ions, the second dopant ions including lanthanum ions, titanium ions, zirconium ions, tantalum ions, niobium ions, or manganese ions.

In some embodiments, a top surface of the first gate is flush with a top surface of the second gate.

An embodiment of the present disclosure further provides a method for preparing a semiconductor structure, including: providing a substrate, including a PMOS region and an NMOS region; sequentially forming a gate dielectric layer and an initial work function layer on the substrate; performing a first doping treatment on the initial work function layer of the PMOS region and adjusting a work function value of the initial work function layer of the PMOS region, to convert the initial work function layer of the PMOS region into a first work function film; forming a gate electrode film on a surface of the first work function film and on a surface of the initial work function layer of the NMOS region; and etching the gate electrode film, the first work function film, and the initial work function layer of the NMOS region, to form a first gate in the PMOS region and a second gate in the NMOS region, the first gate including a first work function layer and a first gate electrode layer that are stacked, and the second gate including a second work function layer and a second gate electrode layer that are stacked.

In some embodiments, after the first doping treatment, the method further includes: performing a second doping treatment on the initial work function layer of the NMOS region and adjusting a work function value of the initial work function layer of the NMOS region, to convert the initial work function layer of the NMOS region into a second work function film.

In some embodiments, before performing the first doping treatment and the second doping treatment, the method also includes: forming a buffer layer on the surface of the initial work function layer; and after the first doping treatment and the second doping treatment, removing the buffer layer.

In some embodiments, the buffer layer has a thickness of 2 nm to 7 nm.

In some embodiments, dopant ions used in the first doping treatment include aluminum ions, cobalt ions, nickel ions, ruthenium ions, rhodium ions, palladium ions, rhenium ions, iridium ions or platinum ions, and dopant ions used in the second doping treatment include lanthanum ions, titanium ions, zirconium ions, tantalum ions, niobium ions or manganese ions.

In some embodiments, the first doping treatment is performed by a first ion implantation process; and/or the second doping treatment is performed by a second ion implantation process.

In some embodiments, process parameters of the first ion implantation process include: implanted ions being aluminum ions, implanted energy of the aluminum ions being 0.1 keV to 16 keV, and an implanted dose of the aluminum ions being 1e¹⁴ to 5e¹⁶/cm².

In some embodiments, process parameters of the second ion implantation process include: implanted ions being lanthanum ions, implanted energy of the lanthanum ions being 0.1 keV to 20 keV, and an implanted dose of the lanthanum ions being 1e¹⁴ to 5e¹⁶/cm².

In some embodiments, the first doping treatment is performed by a thermal diffusion process; and/or the second doping treatment is performed by a thermal diffusion process.

In some embodiments, process steps for forming the first gate and the second gate include: forming a patterned photoresist layer on a surface of the gate electrode film; etching, using a dry etching process, the gate electrode film, the first work function film, and the second work function film of both the PMOS region and the NMOS region by using the patterned photoresist layer as a mask; and removing the patterned photoresist layer.

In some embodiments, a material of the initial work function layer includes TiN.

In some embodiments, the gate electrode film includes a polysilicon film, a barrier film, a conductive film, and a protective film that are sequentially stacked; and process steps for forming the first gate and the second gate include: forming a patterned photoresist layer on a surface of the protective film; etching, using a dry etching process, the polysilicon film, the barrier film, the conductive film, the protective film, the first work function film, and the second work function film of both the PMOS region and the NMOS region by using the patterned photoresist layer as a mask; and removing the patterned photoresist layer.

In some embodiments, after forming the first gate and the second gate, the method further includes: forming a spacer layer between the first gate and the second gate; and forming source and drain regions on both sides of the first gate and the second gate.

The technical solutions provided in the embodiments of the present disclosure have at least the following advantages:

The method for preparing a semiconductor structure provided in the embodiments of the present disclosure simplifies the process for preparing the semiconductor structure, solves the problem of uneven etching caused by different thicknesses of the work function layers of the PMOS transistor and the NMOS transistor, and improves the yield and reliability of semiconductor devices. In the embodiments of the present disclosure, the stacking height of the PMOS region is reduced by performing the first doping treatment on the initial work function layer of the PMOS region to form the first work function layer. In the embodiments of the present disclosure, the height of the first gate in the PMOS region is reduced by simplifying the process steps, so that the height of the first gate in the PMOS region and that of the second gate in the NMOS region are approximately the same, to alleviate the uneven etching of the PMOS region and the NMOS region. In addition, due to the simplified preparation process, the work function value of the initial work function layer of the PMOS region is easier to adjust, thereby increasing the process window, reducing the cost, and improving the yield and reliability of semiconductor devices.

### BRIEF DESCRIPTION OF THE DRAWINGS

One or more embodiments are exemplarily illustrated by the pictures in the accompanying drawings, which do not constitute a limitation to the embodiments, and unless specifically stated, the figures in the accompanying drawings do not conform to a scale. To explain the embodiments of the present disclosure or the technical solutions in the conventional technology more clearly, the following will briefly describe the accompanying drawings that need to be used in the description of the embodiments. Obviously, the accompanying drawings in the following description illustrate only some embodiments of the present disclosure, and those of ordinary skill in the art can still derive other accompanying drawings from these accompanying drawings without creative efforts.

FIG. 1 is a schematic diagram of a semiconductor structure according to an embodiment of the present disclosure.

FIG. 2 is a schematic flowchart of a method for preparing a semiconductor structure according to an embodiment of the present disclosure.

FIG. 3 to FIG. 13 are schematic cross-sectional structural diagrams corresponding to steps of a method for preparing a semiconductor structure according to various embodiments of the present disclosure.

FIG. 14 is a schematic diagram of a semiconductor structure according to another embodiment of the present disclosure.

FIG. 15 is a schematic flowchart of a method for preparing a semiconductor structure according to another embodiment of the present disclosure.

FIG. 16 to FIG. 26 are schematic cross-sectional structural diagrams corresponding to steps of a method for preparing a semiconductor structure according to various embodiments of the present disclosure.

### DETAILED DESCRIPTION OF THE EMBODIMENTS

As the feature sizes of MOS devices become smaller and smaller, in order to achieve a large saturation current, threshold voltages of the transistors need to be reduced. Among various implementable solutions, one method is to use a metal gate having a work function to reduce the threshold voltages of the transistors. In addition, for two different transistors in a MOS device, respectively, a PMOS transistor and an NMOS transistor, metal gates having two different work functions need to be used. That is, a dual-work function metal gate, as a gate electrode of the PMOS transistor and a gate electrode of the NMOS transistor, respectively. The MOS device formed in this way is widely accepted by the industry due to its excellent device performance and easy compatibility with MOS processes. Generally, the use of different materials to obtain a dual-work function metal gate requires a high metal etching technology, increases the process flow and the complexity of the process.

As mentioned in the BACKGROUND, the methods for fabricating a metal gate mainly include a gate-first process and a gate-last process. The gate-last process is more complex and has a die density smaller than that of the gate-first process under the same condition. The key problem of the gate-first process is to control the threshold voltage Vt of the PMOS transistor. To obtain the preset threshold voltage Vt, the work function of the metal gate in the PMOS transistor is generally between 4.8 eV and 5.1 eV, and the work function of the metal gate in the NMOS transistor is generally between 4.0 eV and 4.3 eV.

A semiconductor structure in the related art generally includes a substrate, including a PMOS region and an NMOS region, the PMOS region and the NMOS region being isolated by a Shallow Trench Isolation (STI) structure. A gate dielectric layer is provided on the substrate of the PMOS region and of the NMOS region, where the gate dielectric layer includes silicon dioxide or a high-k material. The semiconductor structure further includes a first gate structure in the PMOS region and a second gate structure in the NMOS region. The first gate structure includes a first work function layer and a first gate electrode layer that are stacked. The second gate structure includes a second work function layer and a second gate electrode layer that are stacked, and a second work function layer is further disposed above the first work function layer.

In the semiconductor structure, work function adjustment of the PMOS region is performed through the first work function layer, and work function adjustment of the NMOS region is performed through the second work function layer, so that the PMOS region and the NMOS region reach their respective threshold voltages. Because the second work function layer is retained above the first work function layer of the first gate structure in the PMOS region and generally the height of the first gate structure in the PMOS region is higher than that of the second gate structure in the NMOS region, uneven etching of the PMOS region and the NMOS region is present in a subsequent etching process. For example, a silicon surface of the NMOS region is over-etched, resulting in damage to the silicon surface. An excessive height of the PMOS region is prone to lead to aluminum oxide residue, resulting in incomplete etching and impacting subsequent ion implantation, and as a result, the yield and reliability of semiconductor devices are degraded.

In addition, the heights of the gate structures in the PMOS region and the NMOS region are different. The height of the first gate structure in the PMOS region is higher than that of the second gate structure in the NMOS region, uneven etching of the PMOS region and the NMOS region is present in a subsequent etching process, and the yield and reliability of semiconductor devices are degraded. Moreover, the first work function layer and the second work function layer need to be formed by a deposition method such as Chemical Vapor Deposition (CVD) or Physical Vapor Deposition (PVD). Due to the impact of the deposition process, the work functions of the first work function layer and the second work function layer are not easy to control and the accuracy is low, resulting in unstable threshold voltages of the MOSFETs. Therefore, in the process of fabricating a gate-first electrode, how to stably and accurately control the work function of the work function layer has become an urgent problem to be solved by those skilled in the art.

To ensure the uniformity of the PMOS region and the NMOS region in the subsequent etching process, an embodiment of the present disclosure provides a semiconductor structure, including: a substrate, a gate dielectric layer, a first gate in the PMOS region, and a second gate in the NMOS region; the substrate includes the PMOS region and the NMOS region, and the gate dielectric layer is located on the substrate of the PMOS region and of the NMOS region; and the first gate includes a first work function layer and a first gate electrode layer that are stacked, and the second gate includes a second work function layer and a second gate electrode layer that are stacked, the first work function layer being formed based on a first doping treatment of an initial work function layer. In the embodiment of the present disclosure, the first work function layer is formed by performing the first doping treatment on the initial work function layer of the PMOS region, which simplifies the process steps and reduces the height of the gate structure in the PMOS region, so that the height of the gate structure in the PMOS region and that of the gate structure in the NMOS region are approximately the same, to alleviate the uneven etching. In addition, by simplifying the preparation process, the work function value of the initial work function layer of the PMOS region is easier to adjust, thereby increasing the process window, reducing the cost, and improving the yield and reliability of semiconductor devices.

The following describes the embodiments of the present disclosure in detail in combination with the accompanying drawings. However, those of ordinary skill in the art can understand that in the embodiments of the present disclosure, many technical details are proposed in order to enable readers to better understand the embodiments of the present disclosure. However, even without these technical details and various changes and modifications based on the following embodiments, the technical solutions claimed by the embodiments of the present disclosure can be implemented.

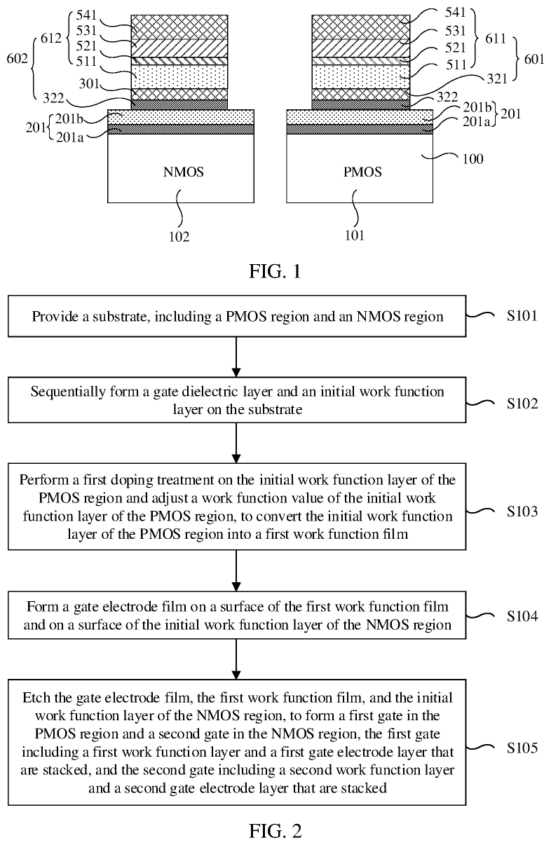

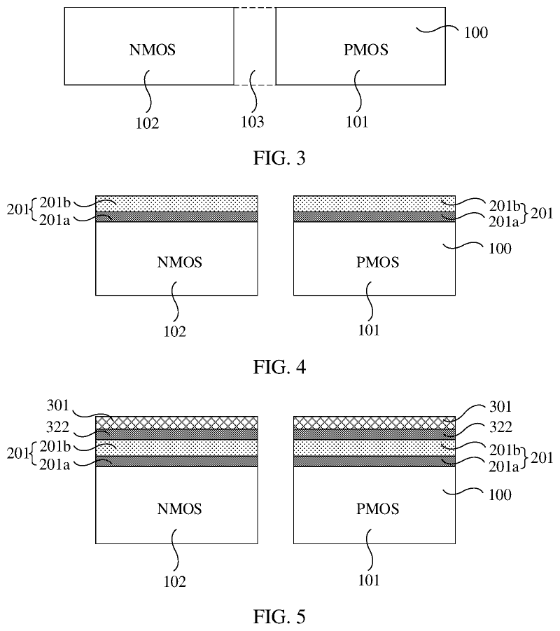

An embodiment of the present disclosure provides a semiconductor structure. The semiconductor structure provided in an embodiment of the present disclosure is described in detail below with reference to the accompanying drawings. FIG. 1 is a schematic diagram of a semiconductor structure according to an embodiment of the present disclosure. FIG. 2 is a schematic flowchart of a method for preparing a semiconductor structure according to the embodiment of the present disclosure. It should be noted that, in order to facilitate description and clearly illustrate steps of the method for preparing a semiconductor structure, FIG. 3 to FIG. 13 are schematic structural diagrams of portions of the semiconductor structure.

Referring to FIG. 1, an aspect of the embodiments of the present disclosure provides a semiconductor structure, including: a substrate 100, a gate dielectric layer 201, a first gate 601 in a PMOS region 101, and a second gate 602 in an NMOS region 102; and the substrate 100 includes the PMOS region 101 and the NMOS region 102. The gate dielectric layer 201 is located on the substrate 100 of the PMOS region 101 and of the NMOS region 102; the first gate 601 includes a first work function layer 321 and a first gate electrode layer 611 that are stacked, and the second gate 602 includes a second work function layer 322 and a second gate electrode layer 612 that are stacked. The first work function layer 321 is formed based on a first doping treatment of an initial work function layer 301.

In some embodiments, the first work function layer 321 is doped with first dopant ions, the first dopant ions including aluminum ions, cobalt ions, nickel ions, ruthenium ions, rhodium ions, palladium ions, rhenium ions, iridium ions, or platinum ions.

In some embodiments, a material of the second work function layer 322 includes lanthanum oxide, titanium oxide, zirconium oxide, tantalum oxide, niobium oxide, or manganese oxide. In an embodiment of the present disclosure, a material of the second work function layer 322 is lanthanum oxide, which is formed of a lanthanum oxide material layer deposited on the gate dielectric layer 201.

To reduce the stacking height difference between the PMOS region 101 and the NMOS region 102, in the embodiment of the present disclosure, the second work function layer 322 is formed on the gate dielectric layer of both the PMOS region 101 and the NMOS region 102, the initial work function layer is formed on the second work function layer 322, and the first doping treatment is performed on the initial work function layer 301 of the PMOS region 101, to convert the initial work function layer 301 of the PMOS region 101 into the first work function layer 321, so as to adjust the work function of the initial work function layer 301 of the PMOS region 101.

The second work function layer 322 is deposited on a surface of the gate dielectric layer 201 of the PMOS region 101 and the NMOS region 102, and therefore the second work function layer 322 is formed at both the PMOS region 101 and the NMOS region 102. For example, aluminum ions are used to adjust the initial work function layer 301 (for example, a titanium nitride layer) in the PMOS region 101, so that the initial work function layer 301 of the PMOS region 101 is converted into the first work function layer 321, to adjust its work function. It can be understood that, to reduce side effects of the second work function layer 322 on the PMOS region 101, for example, an implanted dose of aluminum ions implanted into the initial work function layer 301 of the PMOS region 101 is relatively high. If the material of the second work function layer 322 is lanthanum oxide, a relatively high dose of aluminum ions is implanted into the initial work function layer 301 of the PMOS region 101 to eliminate the impact of lanthanum ions on the PMOS region 101.

In some embodiments, a top surface of the first gate 601 is flush with a top surface of the second gate 602.

It should be noted that, affected by the deposition process, the top surface of the first gate 601 is approximately flush with the top surface of the second gate 602, to ensure that the heights of the PMOS region 101 and the NMOS region 102 are consistent.

Still referring to FIG. 1, the second work function layer 322 is located on the gate dielectric layer 201, and the PMOS region 101 and the NMOS region 102 are both provided with the second work function layer 322, to ensure that the heights of the first gate 601 of the PMOS region 101 and the second gate 602 of the NMOS region 102 are approximately equal, that is, the top surface of the first gate 601 is approximately flush with the top surface of the second gate 602, to solve uneven etching caused by inconsistent heights of the PMOS region 101 and the NMOS region 102.

Referring to FIG. 2, the method for preparing a semiconductor structure includes the following steps:

Step S101: Provide a substrate, including a PMOS region and an NMOS region.

Step S102: Sequentially form a gate dielectric layer and an initial work function layer on the substrate.

Step S103: Perform a first doping treatment on the initial work function layer of the PMOS region to adjust a work function value of the initial work function layer of the PMOS region, to convert the initial work function layer of the PMOS region into a first work function film.

Step S104: Form a gate electrode film on a surface of the first work function film and on a surface of the initial work function layer of the NMOS region.

Step S105: Etch the gate electrode film, the first work function film, the initial work function layer of the NMOS region, and the second work function layer to form a first gate in the PMOS region and a second gate in the NMOS region, the first gate including a first work function layer and a first gate electrode layer that are stacked, and the second gate including the second work function layer and a second gate electrode layer that are stacked.

The method for preparing a semiconductor structure of the embodiment of the present disclosure is described in detail below with reference to the accompanying drawings.

Referring to FIG. 3, a substrate 100, that is, a semiconductor substrate, is provided, where a shallow trench isolation (STI) structure 103 is formed on the substrate 100, and well region implantation is carried out, to form a PMOS transistor formation region and an NMOS formation region, referred to as a PMOS region 101 and an NMOS region 102 for short.

In some embodiments, the method for forming the STI structure 103 on the substrate 100 includes: first coating a photoresist on the substrate 100, then performing lithography to obtain an STI structure pattern, and anisotropically etching the substrate 100 to obtain a shallow trench; and filling the shallow trench with a dielectric material, generally, such as silicon dioxide (SiO₂), to form the STI structure 103. After the STI structure 103 is formed, well region implantation is carried out. Implanted impurities in the PMOS region 101 are N-type impurities, and implanted impurities in the NMOS region 102 are P-type impurities.

In some embodiments, the substrate 100 is a single crystal silicon substrate. In some embodiments, the substrate 100 may also be another suitable semiconductor substrate, such as a Silicon-On-Insulator (SOI) substrate or a silicon germanium (GeSi) substrate.

It should be noted that the substrate 100 may be P type or N type. In the embodiment of the present disclosure, the substrate 100 is a P-type substrate.

Referring to FIG. 4, a gate dielectric layer 201 is formed on the substrate 100. A material of the gate dielectric layer 201 may be a conventional gate dielectric material such as silicon dioxide, or may be a high-K (dielectric constant) dielectric material. A high-K material has a dielectric constant greater than that of the silicon dioxide, and may provide better performance for transistor devices.

As a gate insulating layer of a MOS transistor, the gate dielectric layer 201 not only needs to implement its gate insulating property, but also needs to have a thickness as thin as possible. When the material of the gate dielectric layer 201 is a high-K material, the thickness of the gate dielectric layer 201 is about 2 nm to 4 nm; and when the material of the gate dielectric layer 201 is a silicon dioxide, the thickness of the gate dielectric layer 201 is about 5 nm to 7 nm. In this embodiment, the gate dielectric layer 201 includes an interface layer 210a and a high-K material layer 201b that are stacked, the interface layer 210a being located under the high-K material layer 201b. In some embodiments, the material of the interface layer 201a is silicon dioxide. The material of the high-K material layer 201b is a high-K material such as a binary or multi transition metal oxide or a lanthanides oxide. For example, the high-K material may be hafnium dioxide or hafnium silicon oxide, or may be lanthanum oxide, lanthanum-aluminum oxide, zirconium oxide, zirconium-silicon oxide, tantalum oxide, titanium oxide, barium-strontium-titanium oxide, barium-titanium oxide, strontium-titanium oxide, yttrium oxide, aluminum oxide, lead-scandium-tantalum oxide, or lead zinc niobate.

Referring to FIG. 5, the second work function layer 322 and the initial work function layer 301 are sequentially formed on the gate dielectric layer 201.

In the embodiment of the present disclosure, the material of the second work function layer 322 is lanthanum oxide. Certainly, the second work function layer 322 may be made of another material, such as titanium oxide, zirconium oxide, tantalum oxide, niobium oxide, or manganese oxide.

In the embodiment of the present disclosure, the material of the initial work function layer 301 is titanium nitride. Because the work function of the titanium nitride is correlated with its thickness, at a given temperature, a greater thickness of the titanium nitride indicates a greater work function, and in order to enable the work functions of the first work function layer and the second work function layer to meet requirements, the thickness of the initial work function layer 301 may be 2 nm to 15 nm, for example, 3 nm, or 10 nm. Certainly, the initial work function layer 301 may be made of another material, such as tantalum nitride (TaN) or molybdenum nitride (MoN).

In some embodiments, the deposition processes of the gate dielectric layer 201, the second work function layer 322, and the initial work function layer 301 may be, for example, Atomic Layer Deposition (ALD), CVD, or PVD, which are well known to those skilled in the art, and therefore details are not described herein.

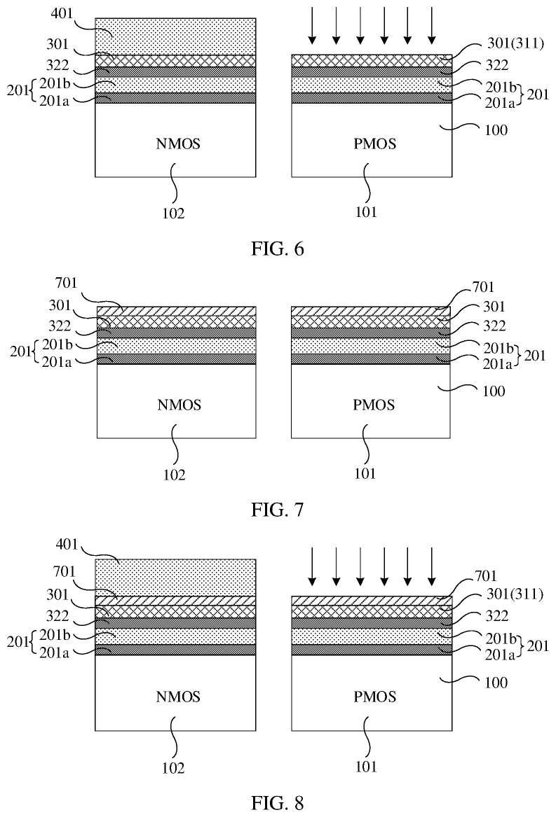

Referring to FIG. 6, the first doping treatment is performed on the initial work function layer 301 of the PMOS region 101 to adjust the work function value of the initial work function layer 301 of the PMOS region 101, to convert the initial work function layer 301 of the PMOS region 101 into the first work function film. Here, the work function of the initial work function layer 301 of the PMOS region 101 refers to a work function that can meet a threshold voltage requirement of the PMOS transistor, specifically, between 4.8 eV and 5.1 eV. It should be noted that the values are only examples and should not limit the protection scope of the present disclosure. That is, the work function of the first work function film 101 of the PMOS region can be greater than or equal to 4.8 eV and less than or equal to 5.1 eV.

In some embodiments, dopant ions used in the first doping treatment includes one or more of aluminum ions, cobalt ions, nickel ions, ruthenium ions, rhodium ions, palladium ions, rhenium ions, iridium ions, or platinum ions.

In some embodiments, the first doping treatment includes ion implantation, thermal diffusion, or sputtering process. For example, dopant ions used in the first doping treatment are aluminum ions, and the work function value of the initial work function layer of the PMOS region is adjusted by the aluminum ions, which is convenient to adjust and improve the accuracy of adjustment of the work function. By adjusting process parameters of doping the aluminum ions, the work function value of the initial work function layer of the PMOS region can be adjusted, thereby simplifying the process.

In some embodiments, the first doping treatment is performed by a first ion implantation process.

In some embodiments, process parameters of the first ion implantation process include: implanted ions being aluminum ions, implanted energy of the aluminum ions being 0.1 keV to 16 keV, for example, 0.5 keV, 3 keV, 8 keV, or 13 keV, and an implanted dose of the aluminum ions being 1e¹⁴ to 5e¹⁶/cm², for example, 5e¹⁴/cm², 5e¹⁵/cm², 8e¹⁵/cm², or 1e¹⁶/cm².

Referring to FIG. 6, process steps of the first ion implantation process include: forming a first mask layer 401 on a surface of the initial work function layer 301, and performing lithography on the first mask layer 401 to remove the first mask layer 401 corresponding to the PMOS region; and using the remaining first mask layer 401 as a mask, and performing the first doping treatment on the initial work function layer 301 of the PMOS region 101 by using aluminum ions to adjust the work function value of the initial work function layer 301 of the PMOS region 101, to convert the initial work function layer 301 of the PMOS region 101 into the first work function film 311.

It should be noted that, as shown in FIG. 6, the implanted aluminum ions are disposed in the initial work function layer 301 corresponding to the PMOS region 101, to convert the initial work function layer 301 corresponding to the PMOS region 101 into the first work function film 311. The implanted aluminum ions are located at a junction of the initial work function layer 301 corresponding to the PMOS region 101 and the gate dielectric layer 201, to produce an electric dipole effect, thereby adjusting the work function. In this embodiment, implanting the aluminum ions into the initial work function layer 301 corresponding to the PMOS region 101 increases the work function value of the first work function film 311, so that the work function of the first work function film 311 can meet the requirement of the work function of the first gate in the PMOS region 101.

In some embodiments, before performing the first doping treatment, the method further includes: forming a buffer layer 701 (FIG. 7) on the surface the initial work function layer 301; and after the first doping treatment, removing the buffer layer 701.

Referring to FIG. 7, before performing the first doping treatment, the buffer layer 701 is formed on the surface of the initial work function layer 301 by a deposition process. The deposition process of the buffer layer 701 may be, for example, ALD, CVD, or PVD, which is well known to those skilled in the art, and therefore details are not described herein.

Referring to FIG. 8, the first doping treatment is performed on the initial work function layer 301 of the PMOS region 101 by first ion implantation, and process steps of using the first ion implantation process include: forming a first mask layer 401 on a surface of the buffer layer 701, and performing lithography on the first mask layer 401 to remove the first mask layer 401 corresponding to the PMOS region 101; and using the remaining first mask layer 401 as a mask on the NMOS region 102, and performing the first doping treatment on the initial work function layer 301 of the PMOS region 101 by using aluminum ions, the aluminum ions passing through the buffer layer 701 to enter the initial work function layer 301 of the PMOS region 101 to adjust the work function value of the initial work function layer 301 of the PMOS region 101, to convert the initial work function layer 301 of the PMOS region 101 into the first work function film 311.

It should be noted that, in some embodiments, the first doping treatment may alternatively be performed by a thermal diffusion process.

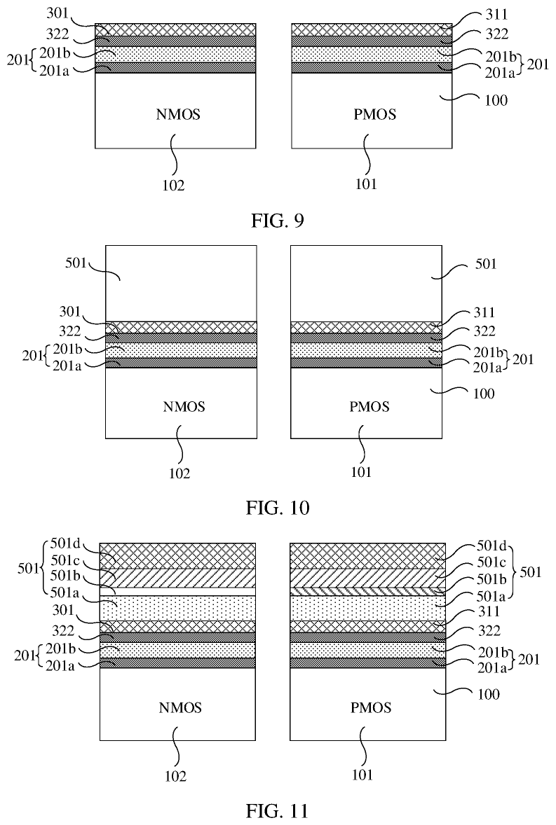

Referring to FIG. 9, after the first doping treatment, the buffer layer 701 on surfaces of the first work function film 311 and the initial work function layer 301 are removed.

In some embodiments, the buffer layer 701 has a thickness of 2 nm to 7 nm, for example, 3 nm, 4 nm, or 5 nm. In this range, it can effectively ensure that metal ions penetrate into the initial work function layer 301 through the buffer layer 701 without adding additional burden, and it is compatible with the process.

In some embodiments, the material of the buffer layer 701 may be polysilicon. The buffer layer 701 acts as a protective layer and a mask layer. During ion implantation, the metal ions penetrate into the initial work function layer 301 through the buffer layer 701, to adjust the work function of the initial work function layer 301.

Referring to FIG. 10, after removing the buffer layer 701 from the surfaces of the first work function film 311 and the initial work function layer 301, a gate electrode film 501 is formed on the surface of the first work function film 311 and on the surface of the initial work function layer 301.

Referring to FIG. 11, in some embodiments, the gate electrode film 501 includes a polysilicon film 501a, a barrier film 501b, a conductive film 501c, and a protective film 501d that are stacked. After removing the buffer layer 701 from the surfaces of the first work function film 311 and the initial work function layer 301, the polysilicon film 501a, the barrier film 501b, the conductive film 501c, and the protective film 501d are sequentially formed on the surface of the first work function film 311 and on the surface of the initial work function layer 301, and then the polysilicon film 501a, the barrier film 501b, the conductive film 501c, and the protective film 501d are patterned to form a polysilicon conductive layer 511, a barrier layer 521, a conductive layer 531, and a protective layer 541. The deposition process of the polysilicon film 501a, the barrier film 501b, the conductive film 501c, and the protective film 501d may be, for example, ALD, CVD, or PVD, which is well known to those skilled in the art, and therefore details are not described herein.

In some embodiments, the polysilicon film 501a is made of doped polysilicon, in-situ doped polysilicon, and/or polysilicon made of crystalized amorphous silicon. For example, the polysilicon film 501a may be doped polysilicon, or may be polysilicon made of in-situ doped poly silicon or crystalized amorphous silicon.

In some embodiments, the material of the barrier film 501b is metal silicide. For example, the material of the barrier film 501b may be titanium nitride silicide (TiSiN). The barrier film 501b is mainly configured to connect a semiconductor and a metal, to reduce the Schottky barrier height.

In some embodiments, the material of the conductive film 501c is a conductive material. For example, the material of the conductive film 501c may be tungsten, titanium, or aluminum. In other embodiments, the material of the conductive film 501c may be one or more of titanium tungsten and titanium nitride. When the conductive film 501c includes a plurality of materials, the conductive film 501c may be formed by simultaneously depositing a plurality of materials, such that components of the materials are uniformly distributed in the conductive film 501c.

In some embodiments, the material of the protective film 501d is silicon dioxide or silicon nitride.

In some embodiments, the gate electrode film 501, the first work function film 311, the initial work function layer 301, and the second work function layer 322 are etched to form a first gate in the PMOS region 101 and a second gate in the NMOS region 102, the first gate including a first work function layer 311 and a first gate electrode layer that are stacked, and the second gate including a second work function layer 312 and a second gate electrode layer that are stacked.

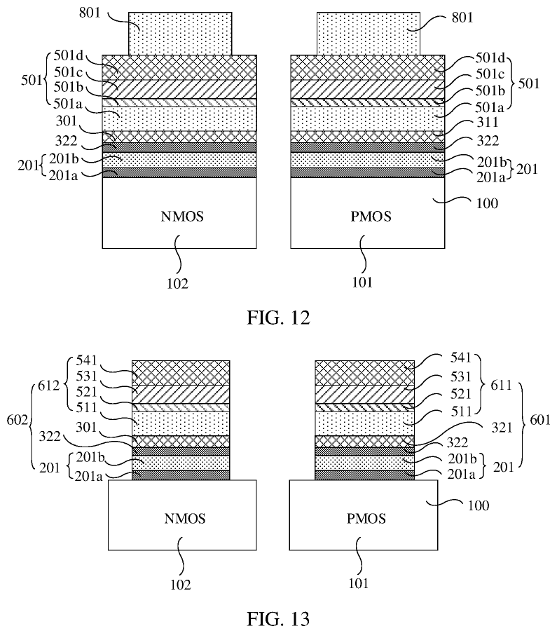

Referring to FIG. 12, in some embodiments, process steps of forming the first gate and the second gate include: forming a patterned photoresist layer 801 on a surface of the gate electrode film 501; etching, using a dry etching process, the gate electrode film 501, the first work function film 311, and the initial work function layer 302 of the PMOS region 101 and the NMOS region 102 by using the patterned photoresist layer 801 as a mask; and removing the patterned photoresist layer 801.

Referring to FIG. 1, in some embodiments, the gate electrode film 501, the first work function film 311, the initial work function layer 301, and the second work function layer 322 are etched. The etching is stopped on the surface of the gate dielectric layer 201. A first gate 601 in the PMOS region 101 and a second gate 602 in the NMOS region 102 are formed by the etching process, to obtain the semiconductor structure.

Still referring to FIG. 1, in a case that the gate electrode film 501 includes a polysilicon film 501a, a barrier film 501b, a conductive film 501c, and a protective film 501d that are stacked, by etching the protective film 501d, the conductive film 501c, the barrier film 501b, and the polysilicon film 501a 102 of both the PMOS region 101 and the NMOS region, and etching both the first work function film 311 of the PMOS region 101 and the initial work function layer 301 of the NMOS region 102, the first gate 601 in the PMOS region 101 and the second gate 602 in the NMOS region 102 are formed. The first gate 601 includes a first work function layer 321 and a first gate electrode layer 611 located on a surface of the first work function layer 321 that are stacked, and the second gate 602 includes the initial work function layer 301 and a second gate electrode layer 612 that are stacked. The first gate 601 and the second gate 602 each include a second work function layer 322 on the gate dielectric layer 201; and the first gate electrode layer 611 and the second gate electrode layer 612 each include a polysilicon conductive layer 511, a barrier layer 512, a conductive layer 513, and a protective layer 514 that are stacked.

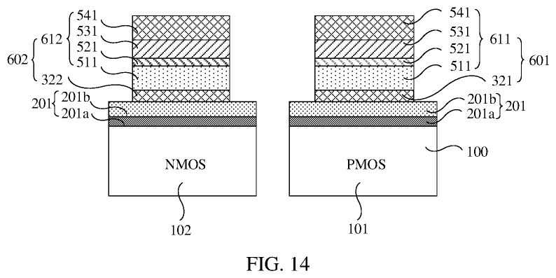

Referring to FIG. 13, in some other embodiments, after the gate electrode film 501, the first work function film 311, the initial work function layer 301, and the second work function layer 322 are etched, the gate dielectric layer 201 is further etched, so that the etching stops on the surface of the substrate 100, such that the first gate 601 in the PMOS region 101 and the second gate 602 in the NMOS region 102 are formed by etching, to obtain the semiconductor structure.

In some embodiments, after forming the first gate 601 and the second gate 602, the method further includes: forming a spacer layer between the first gate 601 and the second gate 602; and forming source and drain regions on both sides of the first gate 601 and the second gate 602, so as to form a MOS transistor.

In the foregoing embodiments, the second work function layer 322 is formed on the gate dielectric layer of the PMOS region 101 and the NMOS region 102, and the first doping treatment is performed on the initial work function layer 301 of the PMOS region 101 to obtain the semiconductor structure. The work function value of the initial work function layer 301 of the PMOS region 101 is adjusted by performing the first doping treatment on the initial work function layer 301 of the PMOS region 101, to convert the initial work function layer 301 of the PMOS region 101 into the first work function film 311, to eventually form the first work function layer 321 by etching. In the semiconductor structure prepared in the embodiments, the height of the gate structure of the PMOS region 101 can be reduced as compared to the convention methods. The height difference between the gate structures of the PMOS region 101 and the NMOS region 102 can be reduced or eliminated, and uneven etching of the PMOS region 101 and the NMOS region 102 can be solved.

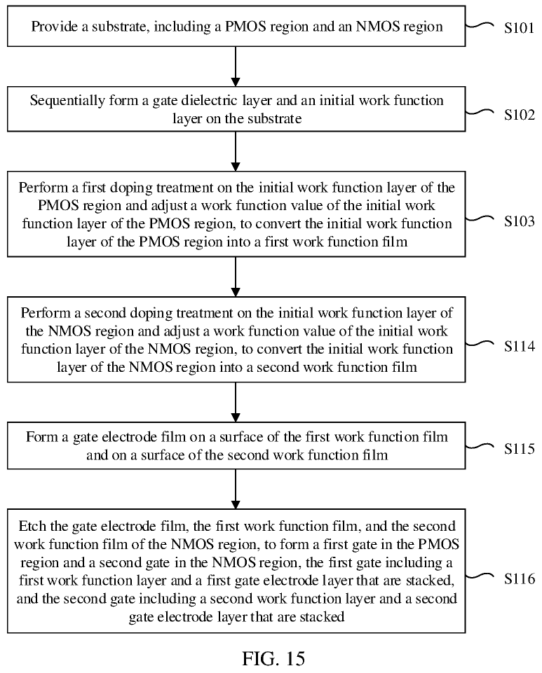

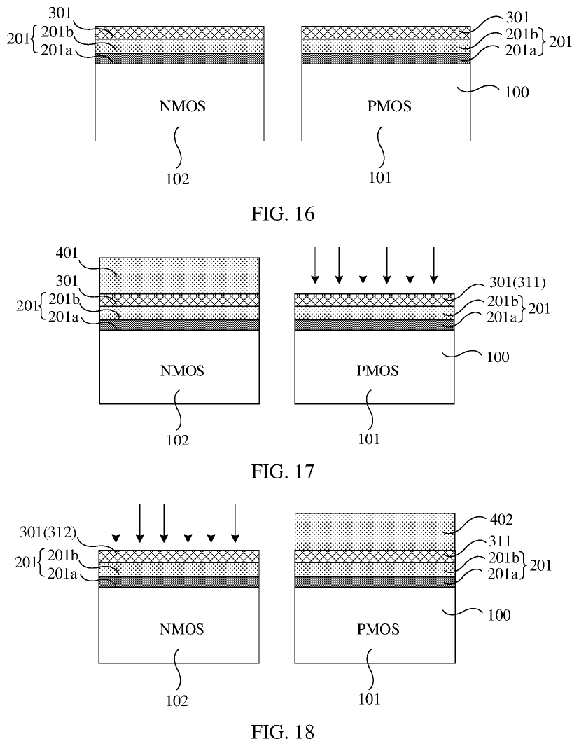

Another embodiment of the present disclosure provides a semiconductor structure. The semiconductor structure provided in the embodiment of the present disclosure is described in detail below with reference to the accompanying drawings. FIG. 14 is a schematic diagram of a semiconductor structure according to another embodiment of the present disclosure. FIG. 15 is a schematic flowchart of a method for preparing a semiconductor structure according to another embodiment of the present disclosure. It should be noted that, in order to facilitate description and clearly illustrate steps of the method for preparing a semiconductor structure, FIG. 16 to FIG. 26 are schematic structural diagrams of portions of the semiconductor structure.

Referring to FIG. 14, an aspect of the embodiments of the present disclosure provides a semiconductor structure, including: a substrate 100, a gate dielectric layer 201, a first gate 601 in a PMOS region 101, and a second gate 602 in an NMOS region 102; and the substrate 100 includes the PMOS region 101 and the NMOS region 102. The gate dielectric layer 201 is located on the substrate 100 of the PMOS region 101 and of the NMOS region 102; the first gate 601 includes a first work function layer 321 and a first gate electrode layer 611 that are stacked, and the second gate 602 includes a second work function layer 322 and a second gate electrode layer 612 that are stacked, the first work function layer 321 being formed based on a first doping treatment of an initial work function layer 301, and the second work function layer 322 being formed based on a second doping treatment of the initial work function layer 301.

In some embodiments, the first work function layer 321 is doped with first dopant ions, the first dopant ions including aluminum ions, cobalt ions, nickel ions, ruthenium ions, rhodium ions, palladium ions, rhenium ions, iridium ions, or platinum ions.

In some embodiments, the second work function layer 322 is doped with second dopant ions, the second dopant ions including lanthanum ions, titanium ions, zirconium ions, tantalum ions, niobium ions, or manganese ions. The second work function layer 322 is formed based on the second doping treatment of the initial work function layer 301 formed on the gate dielectric layer 201 of the NMOS region 102.

In some embodiments, a top surface of the first gate 601 is flush with a top surface of the second gate 602.

It should be noted that, affected by the deposition process, the top surface of the first gate 601 is approximately flush with the top surface of the second gate 602, to ensure that the heights of the PMOS region 101 and the NMOS region 102 are consistent.

Continuously referring to FIG. 14, in the embodiment of the present disclosure, the heights of the first gate 601 of the PMOS region 101 and the second gate 602 of the NMOS region 102 of the semiconductor structure, which is formed by forming the first work function layer 312 by performing the first doping treatment on the initial work function layer 301 of the PMOS region 101 and forming the second work function layer 322 by performing second doping treatment on the initial work function layer 301 of the NMOS region 102, are approximately equal, that is, the top surface of the first gate 601 is approximately flush with the top surface of the second gate 602, to solve uneven etching caused by inconsistent heights of the PMOS region 101 and the NMOS region 102.

Referring to FIG. 15, the method for preparing a semiconductor structure includes the following steps:

Step S101: Provide a substrate, including a PMOS region and an NMOS region.

Step S102: Sequentially form a gate dielectric layer and an initial work function layer on the substrate.

Step S103: Perform a first doping treatment on the initial work function layer of the PMOS region to adjust a work function value of the initial work function layer of the PMOS region, to convert the initial work function layer of the PMOS region into a first work function film.

Step S114: Perform a second doping treatment on the initial work function layer of the NMOS region to adjust a work function value of the initial work function layer of the NMOS region, to convert the initial work function layer of the NMOS region into a second work function film.

Step S115: Form a gate electrode film on a surface of the first work function film and on a surface of the second work function film.

Step S116: Etch the gate electrode film, the first work function film of the PMOS region, and the second work function film of the NMOS region, to form a first gate in the PMOS region and a second gate in the NMOS region, the first gate including a first work function layer and a first gate electrode layer that are stacked, and the second gate including a second work function layer and a second gate electrode layer that are stacked.

In the method for preparing a semiconductor structure according to another embodiment of the present disclosure, the top surface of the first gate 601 and the top surface of the second gate 602 of the semiconductor structure are approximately flush with each other. This is obtained by performing the first doping treatment on the initial work function layer 301 of the PMOS region 101 and performing the second doping treatment on the initial work function layer 301 of the NMOS region 102 to adjust the work function values of the initial work function layer 301 of the PMOS region 101 and the NMOS region 102, to solve uneven etching caused by different heights of the gate structures of the PMOS region 101 and the NMOS region 102.

The method for preparing a semiconductor structure of another embodiment of the present disclosure is described in detail below with reference to the accompanying drawings.

Referring back to FIG. 3, a substrate 100 is provided, a shallow trench isolation (STI) structure 103 is formed on the substrate 100, and a PMOS region 101 and an NMOS region 102 are formed.

Referring back to FIG. 4, a gate dielectric layer 201 is formed on the substrate 100. In this embodiment, the gate dielectric layer 201 includes an interface layer 210a and a high-K material layer 201b that are stacked, the interface layer 210a being located under the high-K material layer 201b. In some embodiments, the material of the interface layer 201a is silicon dioxide. The high-K material layer 201b is a high-K material such as a binary or multi transition metal oxides or a lanthanides oxide.

Referring to FIG. 16, the initial work function layer 301 is formed on the gate dielectric layer 201.

In the embodiment of the present disclosure, the material of the initial work function layer 301 is titanium nitride. In order to enable the work functions of the first work function layer and the second work function layer to meet requirements, the thickness of the initial work function layer 301 may be 2 nm to 15 nm

In some embodiments, the gate dielectric layer 201 and the initial work function layer 301 may be formed by Atomic Layer Deposition (ALD), CVD, or PVD, which are well known to those skilled in the art, and therefore details are not described herein.

Referring to FIG. 17, the first doping treatment is performed on the initial work function layer 301 of the PMOS region 101 to adjust the work function value of the initial work function layer 301 of the PMOS region 101, to convert the initial work function layer 301 of the PMOS region 101 into the first work function film 311.

In some embodiments, dopant ions used in the first doping treatment includes one of aluminum ions, cobalt ions, nickel ions, ruthenium ions, rhodium ions, palladium ions, rhenium ions, iridium ions, or platinum ions.

In some embodiments, the first doping treatment includes ion implantation, thermal diffusion, or sputtering process. For example, dopant ions used in the first doping treatment are aluminum ions, and the work function value of the initial work function layer of the PMOS region is adjusted by the aluminum ions. In the embodiment of the present disclosure, the first doping treatment is performed on the initial work function layer of the PMOS region by a first ion implantation process.

Referring to FIG. 17, process steps of the first ion implantation process include: forming a first mask layer 401 on a surface of the initial work function layer 301, and performing lithography on the first mask layer 401 to remove the first mask layer 401 corresponding to the PMOS region; and using the remaining first mask layer 401 as a mask on the NMOS region 102, and performing the first doping treatment on the initial work function layer 301 of the PMOS region 101 by using aluminum ions to adjust the work function value of the initial work function layer 301 of the PMOS region 101, to convert the initial work function layer 301 of the PMOS region 101 into the first work function film 311.

In some embodiments, dopant ions used in the second doping treatment include lanthanum ions, titanium ions, zirconium ions, tantalum ions, niobium ions, or manganese ions.

In some embodiments, the second doping treatment is performed using a second ion implantation process.

In some embodiments, the second doping treatment includes ion implantation, thermal diffusion, or sputtering process. For example, dopant ions used in the second doping treatment are lanthanum ions, and the work function value of the initial work function layer 301 of the NMOS region 102 is adjusted by the lanthanum ions, which is convenient to adjust and improve the accuracy of adjustment of the work function. By adjusting process parameters of doping the lanthanum ions, the work function value of the initial work function layer 301 of the NMOS region 102 can be adjusted, thereby simplifying the process.

In some embodiments, the process parameters of the second ion implantation process include: implanted ions being lanthanum ions, implanted energy of the lanthanum ions being 0.1 keV to 20 keV, for example, 1 keV, 5 keV, 8 keV, or 16 keV, and an implanted dose of the lanthanum ions being 1e¹⁴ to 5e¹⁶/cm², for example, 2e¹⁴/cm², 5e¹⁴/cm², 8e¹⁴/cm², or 1e¹⁵/cm².

Referring to FIG. 18, process steps of the second ion implantation process include: forming a second mask layer 402 on a surface of the initial work function layer 301, and performing lithography on the second mask layer 402 to remove the second mask layer 402 corresponding to the NMOS region 102; and using the remaining second mask layer 402 as a mask on the PMOS region 101, and performing the second doping treatment on the initial work function layer 301 of the NMOS region 102 by using the lanthanum ions to adjust the work function value of the initial work function layer 301 of the NMOS region 102, to convert the initial work function layer 301 of the NMOS region 102 into the second work function film 312.

It should be noted that, as shown in FIG. 18, the implanted lanthanum ions are located in the initial work function layer 301 corresponding to the NMOS region 102, to convert the initial work function layer 301 corresponding to the NMOS region 102 into the second work function film 312. The implanted lanthanum ions are located at a junction of the second work function film 312 corresponding to the NMOS region 102 and the gate dielectric layer 201, to produce an electric dipole effect, thereby adjusting the work function. In this embodiment, implanting the lanthanum ions into the initial work function layer 301 corresponding to the NMOS region 102 increases the work function value of the second work function film 312, so that the work function of the second work function film 312 can meet the requirement of the work function of the second gate in the NMOS region 102.

It should be noted that, in some embodiments, the second doping treatment may alternatively be performed by a thermal diffusion process.

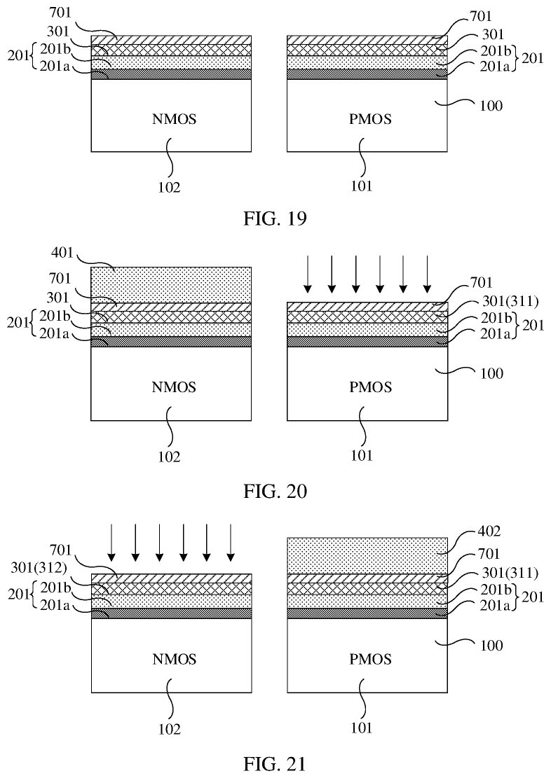

Similarly, referring to FIG. 19, before performing the first doping treatment and the second doping treatment, the buffer layer 701 is formed on the surface of the initial work function layer 301 by a deposition process. After the first doping treatment and the second doping treatment, the buffer layer 701 is removed.

Referring to FIG. 19, before performing the first doping treatment and the second doping treatment, the buffer layer 701 is formed on the surface of the initial work function layer 301 by a deposition process. The deposition process of the buffer layer 701 may be, for example, ALD, CVD, or PVD, which is well known to those skilled in the art, and therefore details are not described herein.

Referring to FIG. 20, the first doping treatment is performed on the initial work function layer 301 of the PMOS region 101 by first ion implantation, and process steps of using the first ion implantation process include: forming a first mask layer 401 on a surface of the buffer layer 701, and performing lithography on the first mask layer 401 to remove the first mask layer 401 corresponding to the PMOS region 101; and using the remaining first mask layer 401 as a mask on the NMOS region 102, and performing the first doping treatment on the initial work function layer 301 of the PMOS region 101 by using aluminum ions, the aluminum ions passing through the buffer layer 701 to enter the initial work function layer 301 of the PMOS region 101 to adjust the work function value of the initial work function layer 301 of the PMOS region 101, to convert the initial work function layer 301 of the PMOS region 101 into the first work function film 311.

Referring to FIG. 21, the second doping treatment is performed on the initial work function layer 301 of the NMOS region 102 by second ion implantation, and process steps of using the second ion implantation process include: forming a second mask layer 402 on a surface of the buffer layer 701, and performing lithography on the second mask layer 402 to remove the second mask layer 402 corresponding to the NMOS region 102; and using the remaining second mask layer 402 as a mask on the PMOS region 101, and performing the second doping treatment on the initial work function layer 301 of the NMOS region 102 by using lanthanum ions, the lanthanum ions passing through the buffer layer 701 to enter the initial work function layer 301 of the NMOS region 102 to adjust the work function value of the initial work function layer 301 of the NMOS region 102, to convert the initial work function layer 301 of the NMOS region 102 into the second work function film 312.

It should be noted that, in some embodiments, the first doping treatment and the second doping treatment may alternatively be performed by a thermal diffusion process.

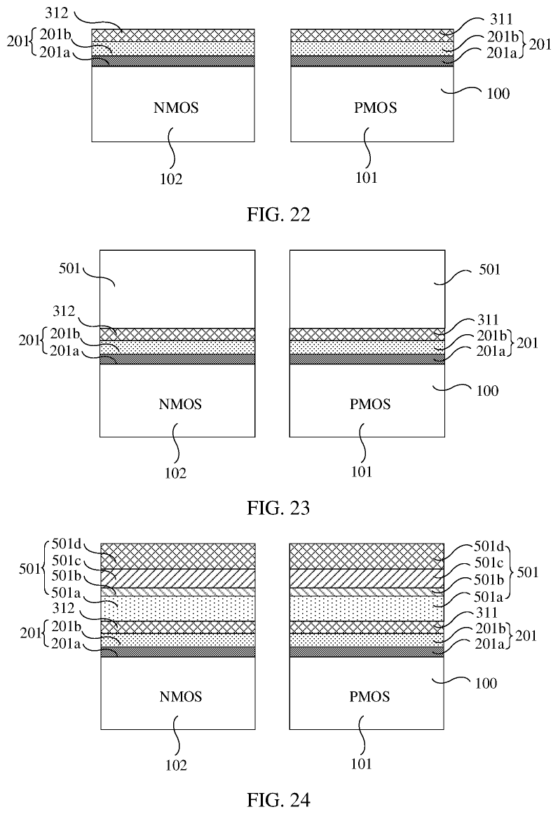

Referring to FIG. 22, after the first doping treatment and the second doping treatment, the buffer layer 701 is removed.

Referring to FIG. 23, after removing the buffer layer 701 from the surfaces of the first work function film 311 and the second work function film 312, a gate electrode film 501 is formed on the surface of the first work function film 311 and on the surface of the second work function film 312.

Referring to FIG. 24, in some embodiments, the gate electrode film 501 includes a polysilicon film 501a, a barrier film 501b, a conductive film 501c, and a protective film 501d that are stacked. After removing the buffer layer 701 from the surfaces of the first work function film 311 and the second work function film 312, the polysilicon film 501a, the barrier film 501b, the conductive film 501c, and the protective film 501d are sequentially formed on the surface of the first work function film 311 and on the surface of the second work function film 312, and then the polysilicon film 501a, the barrier film 501b, the conductive film 501c, and the protective film 501d are etched to form a polysilicon conductive layer 511, a barrier layer 521, a conductive layer 531, and a protective layer 541.

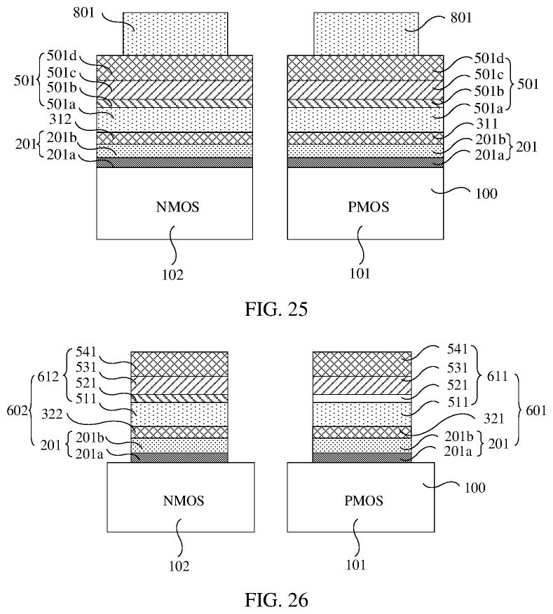

Referring to FIG. 25, in some embodiments, process steps of forming the first gate 601 and the second gate 602 include: forming a patterned photoresist layer 801 on a surface of the gate electrode film 501; etching, using a dry etching process, the gate electrode film 501, the first work function film 311, and the second work function film 312 of the PMOS region 101 and the NMOS region 102 by using the patterned photoresist layer 801 as a mask; and removing the patterned photoresist layer 801.

Referring to FIG. 14, in some embodiments, the gate electrode film 501, the first work function film 311, and the second work function film 312 are etched, the etching is stopped on the surface of the gate dielectric layer 201, and a first gate 601 in the PMOS region 101 and a second gate 602 in the NMOS region 102 are formed by etching, to obtain the semiconductor structure of the embodiment of the present disclosure.

Still referring to FIG. 14, in a case that the gate electrode film 501 includes a polysilicon film 501a, a barrier film 501b, a conductive film 501c, and a protective film 501d that are stacked, by etching the protective film 501d, the conductive film 501c, the barrier film 501b, the polysilicon film 501a, the first work function film 311, and the second work function film 312, a first gate 601 in the PMOS region 101 and a second gate 602 in the NMOS region 102 are formed; the first gate 601 includes a first work function layer 321 and a first gate electrode layer 611 located on a surface of the first work function layer 321 that are stacked, and the second gate 602 includes the initial work function layer 301 and a second gate electrode layer 612 that are stacked; and the first gate electrode layer 611 and the second gate electrode layer 612 each include a polysilicon conductive layer 511, a barrier layer 512, a conductive layer 513, and a protective layer 514 that are stacked.

Referring to FIG. 26, in some other embodiments, after the gate electrode film 501, the first work function film 311, and the second work function film 312 are etched, the gate dielectric layer 201 is further etched, so that the etching stops on the surface of the substrate 100, and the first gate 601 in the PMOS region 101 and the second gate 602 in the NMOS region 102 are formed by etching, to obtain the semiconductor structure.

In some embodiments, after forming the first gate 601 and the second gate 602, the method further includes: forming a spacer layer between the first gate 601 and the second gate 602; and forming source and drain regions on both sides of the first gate 601 and the second gate 602, so as to form a MOS transistor.

In the embodiment of the present disclosure, the first doping treatment is performed on the initial work function layer 301 of the PMOS region 101 by the first ion implantation process, and the second doping treatment is performed on the initial work function layer 301 of the NMOS region 102 by the second ion implantation process, first ions being aluminum ions, and second ions being lanthanum ions, so that the work function value of the initial work function layer 301 of the PMOS region 101 and the work function value of the initial work function layer 301 of the NMOS region 102 are adjusted. In the embodiment of the present disclosure, the height of the first gate 601 in the PMOS region 101 is reduced by simplifying the process steps, so that the height of the first gate 601 in the PMOS region 101 and that of the second gate 302 in the NMOS region 102 are approximately the same, which provides a solution to alleviate the uneven etching of the PMOS region 101 and the NMOS region 102. In addition, by simplifying the preparation process, the work function value of the initial work function layer 301 of the PMOS region 101 and the work function value of the initial work function layer 301 of the NMOS region 102 are easier to adjust, thereby increasing the process window, reducing the cost, and improving the yield and reliability of semiconductor devices.

It can be understood by those of ordinary skill in the art that the implementations are specific embodiments for implementing the present disclosure, and in practical applications, various changes can be made in form and details without departing from the spirit and scope of the present disclosure. Anyone skilled in the art can make their own changes and modifications without departing from the spirit and scope of the present disclosure, and therefore the scope of protection of the present disclosure shall be subject to the scope defined by the claims.

What is claimed is:

1. A semiconductor structure, comprising:
a substrate, comprising a PMOS region and an NMOS region;
a gate dielectric layer, located on the PMOS region and of the NMOS region;
a first gate, located in the PMOS region, the first gate comprising a first work function layer and a first gate electrode layer that are stacked, the first work function layer being formed based on a first doping treatment of an initial work function layer; and
a second gate, located in the NMOS region, the second gate comprising a second work function layer and a second gate electrode layer that are stacked.

2. The semiconductor structure according to claim 1, wherein the first work function layer is doped with first dopant ions, the first dopant ions comprising aluminum ions, cobalt ions, nickel ions, ruthenium ions, rhodium ions, palladium ions, rhenium ions, iridium ions, or platinum ions.

3. The semiconductor structure according to claim 1, wherein the second work function layer is formed based on a second doping treatment of the same initial work function layer.

4. The semiconductor structure according to claim 3, wherein the second work function layer is doped with second dopant ions, the second dopant ions comprising lanthanum ions, titanium ions, zirconium ions, tantalum ions, niobium ions, or manganese ions.

5. The semiconductor structure according to claim 1, wherein a top surface of the first gate is flush with a top surface of the second gate.

6. A method for preparing a semiconductor structure, comprising:
providing a substrate, comprising a PMOS region and an NMOS region;
sequentially forming a gate dielectric layer and an initial work function layer on the substrate;
performing a first doping treatment on the initial work function layer of the PMOS region and adjusting a work function value of the initial work function layer of the PMOS region, to convert the initial work function layer of the PMOS region into a first work function film;
forming a gate electrode film on a surface of the first work function film and on a surface of the initial work function layer of the NMOS region; and
etching the gate electrode film, the first work function film, and the initial work function layer of the NMOS region, to form a first gate in the PMOS region and a second gate in the NMOS region, the first gate comprising a first work function layer and a first gate electrode layer that are stacked, and the second gate comprising a second work function layer and a second gate electrode layer that are stacked.

7. The method for preparing a semiconductor structure according to claim 6, wherein after the first doping treatment, the method further comprises:
performing a second doping treatment on the initial work function layer of the NMOS region and adjusting a work function value of the initial work function layer of the NMOS region, to convert the initial work function layer of the NMOS region into a second work function film.

8. The method for preparing a semiconductor structure according to claim 7, wherein before performing the first doping treatment and the second doping treatment, the method also comprises:
forming a buffer layer on the surface of the initial work function layer; and
after the first doping treatment and the second doping treatment, removing the buffer layer.

9. The method for preparing a semiconductor structure according to claim 8, wherein the buffer layer has a thickness of 2 nm to 7 nm.

10. The method for preparing a semiconductor structure according to claim 7, wherein dopant ions used in the first doping treatment comprise aluminum ions, cobalt ions, nickel ions, ruthenium ions, rhodium ions, palladium ions, rhenium ions, iridium ions or platinum ions, and dopant ions used in the second doping treatment comprise lanthanum ions, titanium ions, zirconium ions, tantalum ions, niobium ions or manganese ions.

11. The method for preparing a semiconductor structure according to claim 7, wherein the first doping treatment is performed by a first ion implantation process; and/or the second doping treatment is performed by a second ion implantation process.

12. The method for preparing a semiconductor structure according to claim 11, wherein process parameters of the first ion implantation process comprise: implanted ions being aluminum ions, implanted energy of the aluminum ions being 0.1 keV to 16 keV, and an implanted dose of the aluminum ions being 1e¹⁴ to 5e¹⁶/cm².

13. The method for preparing a semiconductor structure according to claim 11, wherein process parameters of the second ion implantation process comprise: implanted ions being lanthanum ions, implanted energy of the lanthanum ions being 0.1 keV to 20 keV, and an implanted dose of the lanthanum ions being 1e¹⁴ to 5e¹⁶/cm².

14. The method for preparing a semiconductor structure according to claim 7, wherein the first doping treatment is performed by a thermal diffusion process; and/or the second doping treatment is performed by a thermal diffusion process.

15. The method for preparing a semiconductor structure according to claim 7, wherein a material of the initial work function layer comprises TiN.

16. The method for preparing a semiconductor structure according to claim 7, wherein the gate electrode film comprises a polysilicon film, a barrier film, a conductive film, and a protective film that are sequentially stacked; and
process steps for forming the first gate and the second gate comprise:
forming a patterned photoresist layer on a surface of the protective film;
etching, using a dry etching process, the polysilicon film, the barrier film, the conductive film, the protective film, the first work function film, and the second work function film of both the PMOS region and the NMOS region by using the patterned photoresist layer as a mask; and
removing the patterned photoresist layer.

17. The method for preparing a semiconductor structure according to claim 16, wherein after forming the first gate and the second gate, the method further comprises:
forming a spacer layer between the first gate and the second gate; and
forming source and drain regions on both sides of the first gate and the second gate.
